(19) United States
(12) Patent Application Publication
(10) Pub. No.: US 2007/0143043 A1
(43) Pub. Date: Jun. 21, 2007

(54) System for wireless communications among plural electrical distribution devices of an electrical distribution enclosure

(76) Inventors: John A. Wafer, Moon Township, PA (US); Joseph C. Engel, Monroeville, PA (US); James L. Lagree, Robinson Township, PA (US); Charles J. Luebke, Sussex, WI (US)

Correspondence Address: MARTIN J. MORAN, ESQ.;Eaton Electrical, Inc., Technology & Quality Center, 170 Industry Drive, RIDC Park West, Pittsburgh, PA, 15275-1032, US

(21) Appl. No.: 11/312,024

(22) Filed: Dec. 20, 2005

(51) Int. Cl. G01R 31/00

(52) U.S. Cl. 702/58

(57) ABSTRACT

An electrical distribution system includes a switchgear or motor control center cabinet, a plurality of first protective, metering or control devices internal to the cabinet, and one or more second devices. The second devices include display devices mounted on the cabinet, display devices external to the cabinet and monitoring devices structured to monitor the system and communicate to a remote location. Communications among the first devices and the second devices are wireless communications.

### BACKGROUND OF THE INVENTION

1. Field of the Invention

This invention pertains generally to electrical distribution systems and, more particularly, to such systems providing communications among plural electrical distribution devices of an electrical distribution enclosure.

2. Background Information

An electrical distribution system typically consists of a plurality of protective, metering and control devices mounted within an enclosure, such as a switchgear or motor control center metal cabinet or suitable plastic enclosure. A wired communication mechanism is often provided that allows the various devices to communicate with a display device on the enclosure or to communicate to a remote location, which monitors the condition of the system. The wired communication mechanism within the enclosure typically employs one or more wired field busses.

Electrical distribution devices, such as circuit breakers, are installed within the metal switchgear cabinet. Many of these devices are capable of communicating, for example, on-line data, and alarm/status, cause-of-trip and setpoint information. Typically, the wired field busses are “twisted pair” busses that interconnect the devices to a single node associated with the switchgear cabinet. There are numerous versions of that node including: (1) local nodes with a human machine interface (HMI) (e.g., displays and switches) intended for use on the cabinet; (2) nodes that are “headless” and serve as interfaces or gateways for connecting the devices to one or more remote communication systems; and (3) nodes that serve both the local and remote functions.

FIG. 1 shows an electrical distribution system 2 including a twisted-pair field bus network 4 and a “headless” node 6 that interfaces in-gear field bus communicating devices, such as 7,8,9,10, and an Ethernet communicating system 12.

There is room for improvement in communications in electrical distribution systems.

### SUMMARY OF THE INVENTION

This need and others are met by the present invention which provides a system for wireless communications among plural electrical distribution devices of an electrical distribution enclosure.

In accordance with an aspect of the invention, an electrical distribution system comprises: an enclosure; a plurality of first devices internal to the enclosure, the first devices being protective, metering or control devices; and at least one second device, the at least one second device being mounted on the enclosure, being external to the enclosure or being structured to monitor the system and communicate to a remote location, wherein communications among the first devices and the at least one second device are wireless communications.

The wireless communications may be radio frequency communications.

The radio frequency communications may be provided over a mesh network, a star network or a star-mesh network.

The at least one second device may be a portable wireless communicating device.

The at least one second device may be a display or operator interface which is mounted external to the enclosure.

The at least one second device may be a network gateway device.

The at least one second device may be a human machine interface device mounted external to the enclosure.

The at least one second device may include a network gateway device mounted internal to the enclosure and a display device external to the enclosure.

### BRIEF DESCRIPTION OF THE DRAWINGS

A full understanding of the invention can be gained from the following description of the preferred embodiments when read in conjunction with the accompanying drawings in which:

FIG. 1 is a block diagram of an electrical distribution system including a twisted-pair field bus network and a “headless” node that interfaces in-gear field bus communicating devices and an Ethernet communicating system.

FIG. 2 is an isometric view of an electrical distribution system employing wireless communications among various electrical distribution devices in accordance with the present invention.

FIG. 3 is a block diagram of an electrical distribution system employing wireless communications in a star radio frequency network in accordance with an embodiment of the invention.

FIG. 4 is a block diagram of an electrical distribution system employing wireless communications in a star-mesh radio frequency network in accordance with another embodiment of the invention.

### DESCRIPTION OF THE PREFERRED EMBODIMENTS

As employed herein, the term “wireless” shall expressly include, but not be limited by, radio frequency (RF), infrared, IrDA, low-rate wireless personal area networks (LR-WPANs), other types of wireless sensor networks, wireless area networks, IEEE 802.11 (e.g., 802.11a; 802.11b; 802.11g), IEEE 802.15 (e.g., 802.15.1; 802.15.3, 802.15.4), other wireless communication standards (e.g., without limitation, ZigBee™ Alliance standard), DECT, PWT, pager, PCS, Wi-Fi, Bluetooth™, and cellular.

As employed herein, the term “communication network” shall expressly include, but not be limited by, Ethernet, any local area network (LAN), wide area network (WAN), field bus, intranet, extranet, global communication network, the Internet, and/or wireless communication network.

As employed herein, the term “portable wireless communicating device” shall expressly include, but not be limited by, any portable communicating device having a wireless communication port (e.g., a portable wireless device; a portable wireless display; a portable wireless operator interface; a portable personal computer (PC); a Personal Digital Assistant (PDA); a data phone).

The present invention is described in association with a switchgear system, although the invention is applicable to a wide range of electrical distribution systems (e.g., without limitation, motor control centers (MCCs); packaged controls (e.g., machine/equipment mounted); panelboards; load centers).

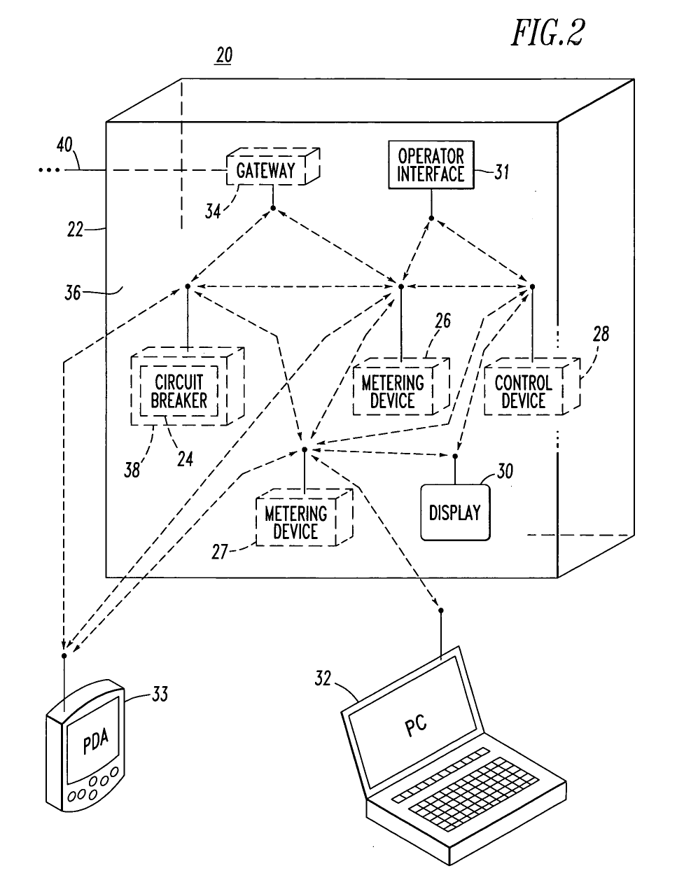

FIG. 2 shows an electrical distribution system 20 including an enclosure 22, a plurality of first devices 24,26,27,28 internal to the enclosure 22, and one or more second devices, such as 30,31,32,33,34. The example first devices 24,26,27,28 include the protective device 24, the metering devices 26,27 and the control device 28. The second devices 30,31,32,33,34 include the devices 30,31 mounted on the enclosure 22, the devices 32,33 external to the enclosure 22, and the monitoring device 34 structured to monitor the system and communicate to a remote location. Communications among the first devices 24,26,27,28 and the second devices 30,31,32,33,34 employ wireless communications.

### EXAMPLE 1

For example, the wireless communications may be RF communications and may be provided by a suitable RF communication network, such as a low-rate wireless personal area network (LR-WPAN), which is a low power short range RF communication network. Examples of suitable transceivers for devices in a LR-WPAN are disclosed in U.S. Patent Application Publication Nos. 2004/0233855; and 2004/0235468, which are incorporated by reference herein.

### EXAMPLE 2

The electrical distribution system enclosure 22 may be, for example, a switchgear or motor control center metal cabinet or suitable plastic enclosure. The wireless communications include both internal and external wireless communications (e.g, wireless data (message) routing) among the internal devices 24,26,27,28,34 and the external devices 30,31,32,33, including the devices 30,31 on the front surface 36 of the enclosure 22. For a motor control center enclosure, for example, the various protective, metering and control devices 24,26,27,28 are typically installed within individual cabinets 38, which are called buckets. For switchgear, for example, these individual cabinets 38 are called cassettes, which may contain circuit breakers. Such devices may also be mounted on bus bars or cables (not shown).

Non-limiting examples of the protective device 24 include circuit breakers, trip units, protective relays and motor overload relays.

Non-limiting examples of the metering devices 26,27 include meters (e.g., panel mounted current/voltage meters; watt-hour meters; power factor meters; power quality meters), voltage, current and/or temperature sensors (e.g., without limitation, mounted on terminals of existing devices; mounted on bus bars (not shown)).

Non-limiting examples of the control device 28 include motor starters, contactors, variable speed drives, timers, programmable logic controllers (PLCs) and other controller devices.

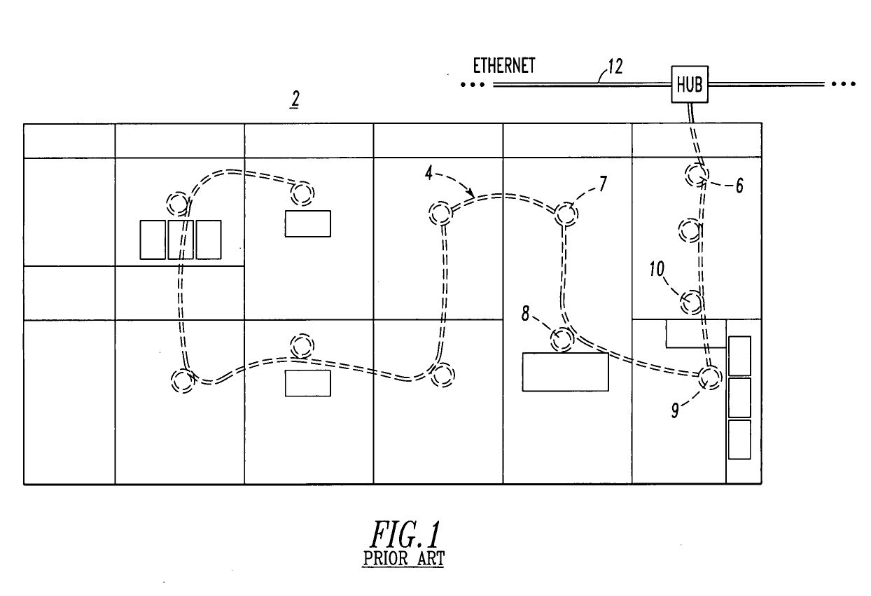

The system 20 eliminates electrical wiring (e.g., the field bus network 4 of FIG. 1) that is now used within switchgear or motor control center cabinets to communicate information from protective, control and/or metering devices to a local/remote display or to a remote computer/data center.

### EXAMPLE 3

At least some of the first devices, such as 24, may be current powered devices. Examples of suitable current powered devices are disclosed in U.S. patent application Ser. Nos. 10/962,682, filed Oct. 12, 2004; and 11/038,899, filed Jan. 19, 2005, which are incorporated by reference herein.

### EXAMPLE 4

The system 20 may include one or more local displays, such as the devices 30 and 31, which may be mounted on the front surface 36 of the enclosure 22, as shown. The system 20 may further include one or more portable wireless communicating devices, such as the devices 32 (e.g., a wireless portable personal computer (PC)) and 33 (e.g., a wireless handheld electronic device (e.g., without limitation, a PDA)) that are preferably at least somewhat remote from the enclosure front surface 36.

### EXAMPLE 5

The monitoring device 34 may be a network gateway device mounted internal to the enclosure 22. This device 34 provides an interface to a communication network 40, which may provide information about the system 20 to a remote location (e.g., without limitation, a data center; another computer; a remote operator interface display; another gateway device) (not shown).

### EXAMPLE 6

The device 31 may be a human machine interface (HMI) device (e.g., an operator interface) internal to or external to the enclosure 22.

### EXAMPLE 7

The devices 30,31 may be displays (e.g., without limitation, display devices; annunciators (e.g., indicator panels; light stack poles)) or operator interfaces which are mounted internal to or external to the enclosure 22, for example, on the external front surface 36 thereof.

### EXAMPLE 8

The device 32 may be, for example, a personal computer (PC) with custom software employed to monitor and/or control the devices 24,26,27,28 within the enclosure 22.

### EXAMPLE 9

A preferred communication mechanism to a remote location is a suitable facility communication network, such as an Ethernet communication network 40. The monitoring device 34 may be a network gateway device (e.g., an RF-to-Ethernet gateway device) mounted external, proximate, on or internal (as shown) to the enclosure 22. This device 34 provides an interface to a wired communication network, such as the example Ethernet communication network 40, which may provide information about the system 20 to a remote location (not shown).

### EXAMPLE 10

The RF communications may be provided over a suitable mesh network. A preferred communication network is a ZigBee™ Alliance standard (Zigbee) network, which employs flexible, multi-hop networking that can follow several architectural topologies, to ensure that a network functions with maximum efficiency and reliability.

As shown in FIG. 2, for maximum flexibility and reliability, Zigbee's mesh topology, where each node (i.e., the various devices 24,26,27,28,30,31,32,33,34) is in direct communication with its immediate neighbor node(s), is an option. If a single node fails for any reason, including the introduction of relatively strong RF interference, then the RF messages are automatically routed through alternate paths.

### EXAMPLE 11

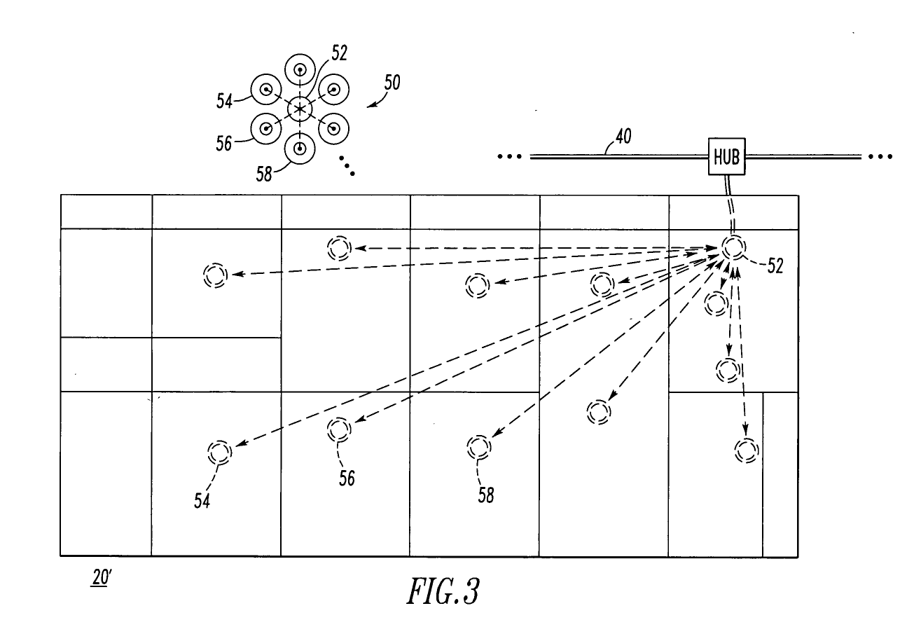

As an alternative to the system 20 employing the mesh network of FIG. 2, the RF communications may be provided over a star network. Referring to FIG. 3, an electrical distribution system 20′ employs a wireless communication network based on a star topology 50 to provide efficient localized (one-hop) communication. In this star network, a central access point (or master) 52 controls communications between nodes (or slaves), such as 54,56,58. However, when physical or RF interference blocks communication between the access point 52 and any of the nodes 54,56,58, the star network cannot recover until the source of the interference is removed or the system 20 selects and migrates to an alternate frequency channel. The example star network topology is a simple wireless communication network consisting of the master 52 and the slaves 54,56,58, such as protective devices (e.g., circuit breakers), metering devices and/or control devices. While relatively simple, this topology requires that each of the slaves 54,56,58 is able to communicate directly back to the master 52.

### EXAMPLE 12

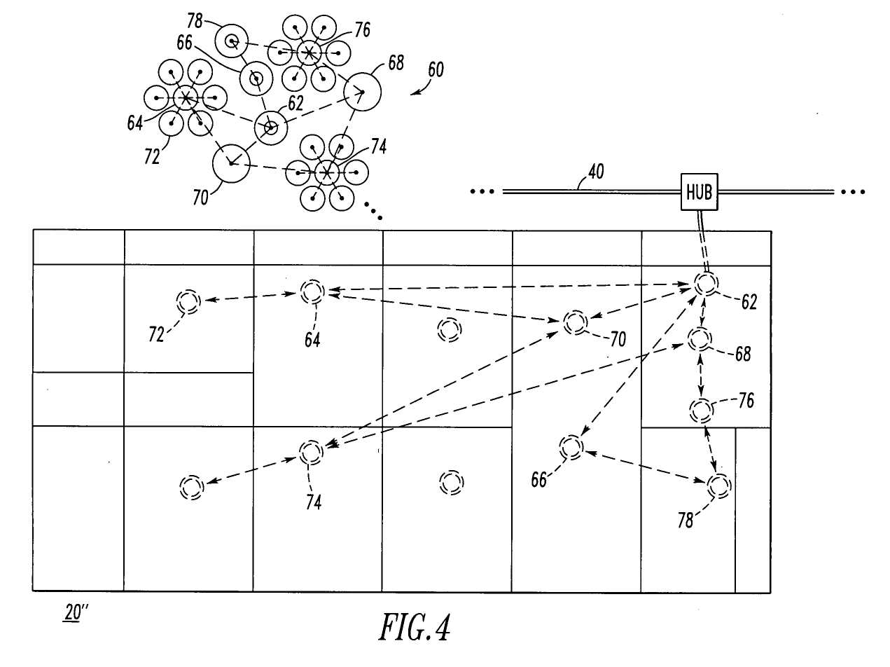

As an alternative to the system 20 employing the mesh network of FIG. 2 or the system 20′ employing the star network of FIG. 3, the RF communications may be provided over a star-mesh network. Referring to FIG. 4, an electrical distribution system 20″ employs a wireless communication network based on a star-mesh topology 60. A star master 62 is powered by a control voltage, while the slaves 64,66,68,70 may be self-powered. The star master 62 is part of a mesh network that allows communication to all of the nodes. Should a mesh node fail, then alternate routing paths will automatically be discovered. A key feature of IEEE 802.15.4 is the concept of meshing. In the example star-mesh network, rather than requiring each node, such as protective devices, metering devices and/or control devices, to communicate to a single node (e.g., the master 52 of FIG. 3), the node only needs to communicate to an adjacent device. For example, the nodes 72,74,76 may communicate through the nodes 64,70,68, respectively, in order to communicate with the master 62. Alternatively, in this example, the node 74 may communicate through the node 68 and the node 76 may communicate through the combination of the nodes 78 and 66 with the master 62. Hence, physical or RF interference is much less of an issue. Information can be routed device-to-device between any two nodes. It is important that any nodes that are essential to routing, such as nodes 64,74,76, be powered and active all the time. In contrast, those nodes, such as 66, that are not essential to routing (since one or more alternate paths exist), do not need to be powered all the time and, thus, that device's electronics may be self powered, for example, by a circuit breaker's load current.

The combined star-mesh topology 60 or superstar configuration combines the benefits of both mesh and star topologies. This is preferably applied in cluster type networks, where the local star nodes, such as 72, are relatively simpler nodes that may be parasitically powered, which communicate to full function nodes, such as 64, that are always powered and have the ability to communicate over a mesh. As such, the superstar topology provides both efficiency and flexibility.

### EXAMPLE 13

Although the above examples assume a complete conversion from wired communications to wireless communications among the various first and second devices associated with the electrical distribution system enclosure 22, it will be appreciated that hybrid communications may be provided for the various first and second devices, such as 24,26,27,28,30,31,32,33,34, such that one or more of such first and second devices is an island of wired components, which island communicates among the other various first and second devices employing wireless communications. In other words, any one or more of the various first and second devices may include plural sub-devices communicating among themselves by wired communications (e.g., without limitation, employing a wired field bus), such that one of such plural sub-devices acts as a single “wireless” node for the other such plural sub-devices and provides wireless communications among the other various first and second devices.

The disclosed systems 20,20′,20″ which employ RF communications, have many advantages over the prior wired system 2 (FIG. 1) including: (1) isolation and immunity from damaging voltage transients; (2) the ability, due to the low power LR-WPAN communications, to add communications to additional devices, such as circuit breakers, without requiring external control power or additional wiring; and (3) at least one communicating node, such as the devices 30,31,32,33, may be outside of the enclosure 22. This feature provides extra safety (e.g., without limitation, from an arc flash) since the user does not need to be directly in front of the enclosure 22, such as a switchgear or motor control center cabinet.

While for clarity of disclosure reference has been made herein to the exemplary display, such as 30, for displaying information pertaining to the system 20, it will be appreciated that such information may be stored, be printed on hard copy, be computer modified, or be combined with other data. All such processing shall be deemed to fall within the terms “display” or “displaying” as employed herein.

While specific embodiments of the invention have been described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of the invention which is to be given the full breadth of the claims appended and any and all equivalents thereof.

What is claimed is:

1. An electrical distribution system comprising:
an enclosure;
a plurality of first devices internal to said enclosure, said first devices being protective, metering or control devices; and
at least one second device, said at least one second device being mounted on said enclosure, being external to said enclosure or being a monitoring device structured to monitor said system and communicate to a remote location,
wherein communications among said first devices and said at least one second device are wireless communications.

2. The electrical distribution system of claim 1 wherein said wireless communications are radio frequency communications.

3. The electrical distribution system of claim 2 wherein said radio frequency communications are provided by a radio frequency communication network.

4. The electrical distribution system of claim 3 wherein said radio frequency communication network is a low-rate wireless personal area network.

5. The electrical distribution system of claim 2 wherein said radio frequency communications are provided over a mesh network.

6. The electrical distribution system of claim 2 wherein said radio frequency communications are provided over a star network.

7. The electrical distribution system of claim 2 wherein said radio frequency communications are provided over a star-mesh network.

8. The electrical distribution system of claim 1 wherein said enclosure is a switchgear or motor control center cabinet.

9. The electrical distribution system of claim 1 wherein at least some of said first devices are current powered devices.

10. The electrical distribution system of claim 1 wherein said first devices are selected from the group consisting of protective devices, control devices and metering devices.

11. The electrical distribution system of claim 10 wherein said protective devices are selected from the group consisting of circuit breakers, trip units, protective relays and motor starters.

12. The electrical distribution system of claim 1 wherein said at least one second device is a portable wireless communicating device.

13. The electrical distribution system of claim 12 wherein said portable wireless communicating device is a personal digital assistant.

14. The electrical distribution system of claim 1 wherein said at least one second device is a display or operator interface which is mounted external to said enclosure.

15. The electrical distribution system of claim 1 wherein said enclosure includes an external surface; and wherein said at least one second device is a display or operator interface which is mounted on the external surface of said enclosure.

16. The electrical distribution system of claim 1 wherein said at least one second device is network gateway device.

17. The electrical distribution system of claim 16 wherein said network gateway device is mounted internal to said enclosure.

18. The electrical distribution system of claim 16 wherein said network gateway device is an Ethernet gateway device.

19. The electrical distribution system of claim 1 wherein said at least one second device is a human machine interface device mounted external to said enclosure.

20. The electrical distribution system of claim 1 wherein said at least one second device includes a network gateway device mounted internal to said enclosure and a display device external to said enclosure.
